(19) United States
(12) Patent Application Publication
(10) Pub. No.: US 2020/0044123 A1
(43) Pub. Date: Feb. 6, 2020

(54) LIGHT SOURCE AND ILLUMINATING DEVICE COMPRISING THE SAME

(71) Applicant: OPPLE LIGHTING CO., LTD., Shanghai (CN)

(72) Inventors: Zhixian Zhou, Shanghai (CN); Jie Qiang, Shanghai (CN)

(73) Assignee: OPPLE LIGHTING CO., LTD., Shanghai (CN)

(21) Appl. No.: 16/594,808

(22) Filed: Oct. 7, 2019

Related U.S. Application Data
(63) Continuation of application No. PCT/CN2018/081969, filed on Apr. 4, 2018.

(30) Foreign Application Priority Data
Apr. 7, 2017 (CN) 201710222531.9
Apr. 7, 2017 (CN) 201720356384.X

(51) Int. Cl. H01L 33/50; F21V 23/00; F21V 23/02

(52) U.S. Cl. CPC H01L 33/504; F21V 23/003; F21Y 2115/10; F21V 23/02; H01L 33/507

(57) ABSTRACT

A light source and an illuminating device utilizing the same are disclosed. The light source includes a blue light-generating unit, a green light-generating unit, and a red light-generating unit. The blue light-generating unit is configured to emit blue light, where the blue light-generating unit is a blue LED chip. The green light-generating unit is configured to emit green light, where the green light-generating unit contains a green fluorophore which absorbs light emitted by the blue light-generating unit and emits green light through wavelength conversion. The red light-generating unit is configured to emit red light.

### CROSS-REFERENCE TO RELATED APPLICATIONS

This application is a continuation application of International Application No. PCT/CN2018/081969, filed with the State Intellectual Property Office of P. R. China on Apr. 4, 2018, which is based upon and claims priority to Chinese Patent Application No. 2017102225319 filed on Apr. 7, 2017 and Chinese Patent Application No. 201720356384X filed on Apr. 7, 2017, the entire contents of which are incorporated herein by reference.

### TECHNICAL FIELD

The present disclosure relates to a light source and an illuminating device, including the light source.

### BACKGROUND

With the arrival and development of the third lighting technology revolution, light-emitting diode (LED) lighting devices are widely used, and users have higher and higher requirements on a light quality thereof. For a long time, research on the light quality has focused only on color rendering index (CRI) and cannot reach a deeper level.

However, it has been found by the lighting industry that, a color rendering evaluation of LED light sources by CRI Ra is not consistent with a visual experience, and for environments with higher color saturation, CRI values usually are not consistent with the users' visual experience, either. It is also pointed out in a report of CIE (International Commission on Illumination) in 2007 that the CRI Ra is not suitable for the evaluation of color rendering property of an LED light source. Organizations such as CIE and IES (Illuminating Engineering Society of North America) have proposed GAI, CQS and other methods for evaluating color rendering capacity of a light source, in succession, so as to supplement the deficiency of CRI. IES officially released a new method for evaluating the color rendering capacity of a light source, i.e., IES TM-30-15 IES Method for Evaluating Light Source Color Rendition, on May 18, 2015. Chip packaging manufacturers and chip application manufacturers have also offered products with higher GAI index, higher CQS index, or better TM30-15 index, in addition to the CRI index, one after another. However, a relationship between a specific index and a visual representation of the product still needs to be verified.

### SUMMARY

The embodiments of the present disclosure provide an LED light source with higher vividness, according to indexes such as CRI, GAI, CQS, and TM30-15.

In a first aspect, the present disclosure provides a light source, including a blue light-generating unit; a green light-generating unit; and a red light-generating unit. The blue light-generating unit is configured to emit blue light, where the blue light-generating unit is a blue LED chip. The green light-generating unit is configured to emit green light, where the green light-generating unit contains a green fluorophore that absorbs light emitted by the blue light-generating unit and emits green light through wavelength conversion. The red light-generating unit is configured to emit red light. The blue light-generating unit, the green light-generating unit, and the red light-generating unit are integrally packaged.

In a second aspect, the present disclosure provides an illuminating device. The illuminating device includes a blue light-generating unit configured to emit blue light, where the blue light-generating unit is a blue LED chip; a green light-generating unit configured to emit green light, where the green light-generating unit contains a green fluorophore that absorbs light emitted by the blue light-generating unit and emits green light through wavelength conversion; and a red light-generating unit configured to emit red light. The illuminating device further includes a power supply connected to the light source and configured to provide the light source with a working power.

### BRIEF DESCRIPTION OF THE DRAWINGS

The drawings described herein are intended to provide a further understanding of the present disclosure and constitute one part thereof. The illustrative embodiments of the present disclosure and the description thereof are used for explaining the present disclosure and do not constitute an inappropriate limitation of the present disclosure.

FIG. 1 is a schematic diagram illustrating an illuminating device, according to an embodiment of the present disclosure;

FIG. 2 is a schematic diagram illustrating the relative spectral energy distribution, according to an embodiment of the present disclosure;

FIG. 3 is a schematic diagram illustrating the distribution of A (λ), according to an embodiment of the present disclosure;

FIG. 4 is a schematic diagram illustrating the relative spectral energy distribution, according to an embodiment of the present disclosure

FIG. 5 is a schematic diagram illustrating the distribution of A (λ), according to an embodiment of the present disclosure;

FIG. 6 is a schematic diagram illustrating the relative spectral energy distribution, according to an embodiment of the present disclosure;

FIG. 7 is a schematic diagram illustrating the distribution of A (λ), according to an embodiment of the present disclosure;

FIG. 8 is a schematic diagram illustrating the relative spectral energy distribution, according to an embodiment of the present disclosure

FIG. 9 is a schematic diagram illustrating the distribution of A (λ), according to an embodiment of the present disclosure;

FIG. 10 is a schematic diagram illustrating the relative spectral energy distribution, according to an embodiment of the present disclosure

FIG. 11 is a schematic diagram illustrating the distribution of A (λ), according to an embodiment of the present disclosure;

FIG. 12 is a schematic diagram illustrating CIE1931 color coordinate, according to an embodiment of the present disclosure; and

FIG. 13 is a structurally schematic diagram illustrating a light source, according to an embodiment of the present disclosure.

### DETAILED DESCRIPTION

A light source and an illuminating device provided by the present disclosure will be described further below in connection with accompanying drawings and particular embodiments.

Reference will now be made in detail to embodiments, examples of which are illustrated in the accompanying drawings. The following description refers to the accompanying drawings in which the same numbers in different drawings represent the same or similar elements unless otherwise represented. The implementations set forth in the following description of the embodiments do not represent all implementations consistent with the invention. Instead, they are merely examples of apparatuses and methods consistent with aspects related to the invention as recited in the appended claims.

The terminology used in the present disclosure is for the purpose of describing particular embodiments only and is not intended to limit the present disclosure. As used in the present disclosure and the appended claims, the singular forms “a,” “an,” and “the” are intended to include the plural forms as well, unless the context clearly indicates otherwise. It shall also be understood that the term “and/or” used herein is intended to signify and include any or all possible combinations of one or more of the associated listed items.

It shall be understood that, although the terms “first,” “second,” “third,” etc. may be used herein to describe various information, the information should not be limited by these terms. These terms are only used to distinguish one category of information from another. For example, without departing from the scope of the present disclosure, the first information may be termed as second information; and similarly, the second information may also be termed as the first information. As used herein, the term “if” may be understood to mean “when” or “upon” or “in response to a judgment” depending on the context.

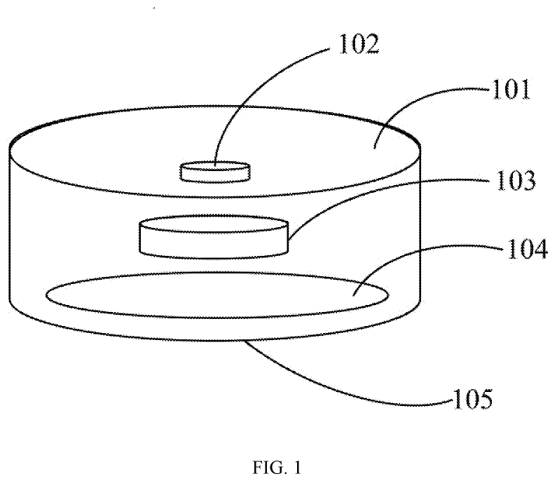

FIG. 1 shows a light fixture 101. The light source provided by the present disclosure is a warm white light source with a color temperature in the range from 2500K to 3600K, and can be applied in a lighting luminaire 101 illustrated in FIG. 1 for daily lighting. The lighting luminaire 101 includes a power driver (not illustrated), a controller 102, a heat dissipation device 103, a lighting source 104 and a lampshade 105, etc. The controller may be configured to adjust light color and light intensity of the lighting source 104, and the lampshade 105 may be replaced by other optical elements in other embodiments, such as a lens, a diffusion element, a photoconductor or the like, in accordance with the design of the luminaire. The heat dissipation device may not be included in the lighting luminaire. The light source 104 includes a blue light-generating e for outputting a blue light component, a green light-generating unit for outputting a yellowish-green light component and a red light-generating unit for outputting a red light component.

These light-generating units for different colors of light in the light source 104 may be LED chips or fluorescent materials capable of converting a wavelength of light, or a combination of LED chips and fluorescent materials. Depending on the difference in color of the emitted light, fluorescent powders of different systems may be adopted as the fluorescent material.

For the blue light-generating unit, a monochromatic LED chip may be adopted, and the monochromatic LED chip used herein refers to an LED chip that gives out light by directly exciting a semiconductor material and has no fluorophore. In addition, it is also possible for the blue light-generating unit to adopt a mode of a LED chip in cooperation with a fluorophore, that is, the blue light-generating unit contains a blue fluorophore which absorbs light emitted by a semiconductor luminous element (LED chip) and emits blue light through wavelength conversion; and the semiconductor luminous element used herein may be a monochromatic LED chip which emits ultraviolet light.

The red light-generating unit is similar to the blue light-generating unit, and may adopt a monochromatic LED chip; moreover, in an embodiment, the red light-generating unit contains a red fluorophore which absorbs light emitted by a semiconductor luminous element and emits red light through wavelength conversion.

And the green light-generating unit includes a green fluorophore which absorbs light emitted by a semiconductor luminous element and emits green light through wavelength conversion. The type of green fluorophore includes aluminate systems such as YAG, Ga-YAG, Lu-AG, TbAG, and so on, silicate system, nitride system, and nitrogen oxide system. The green light-generating unit may be excited by a single type of fluorophore to produce green light, and may also be excited by a combination of two types of fluorophores or more, or even a combination of fluorophores with a variety of peak wavelengths.

When it's the case of a combination of several types of fluorophores, these fluorophores are not confined in one element or component; for example, they may be different green fluorophores in two white LEDs, and a spectral intensity in the range from 510 nm to 580 nm as required can be obtained by superimposing spectrums produced by these fluorophores. This combination of fluorophores is not limited to be used in the green light-generating unit, and when the blue light-generating unit and the red light-generating unit contain fluorophores, they may also use fluorophores with various compositions, and these fluorophores may be distributed in different elements or components.

It should be explained that the “red light-generating unit” and the “green light-generating unit” used herein are merely an expression for describing the present disclosure, and a red fluorophore with a wider emission bandwidth always has part of its energy in a green light domain; in this case, it should be understood that the red fluorophore partly realizes a function of the red light-generating unit and partly contributes to green light emission, that is, the green light-generating unit is composed of a green fluorophore and a red fluorophore.

The design scheme of the light source 104 is finally determined by designing a specific proportion for different generating units, in combination with data of visual experiments. As illustrated in FIG. 15, the blue light-generating unit 1041 is a blue light LED, the green light-generating unit 1042 is a green fluorescent powder, the red light-generating unit 1043 is a red fluorescent powder, and the light source 104 is a white light LED chip; the white light LED chip is packaged and forms a white spectrum with a color temperature in the range between 2500K and 3600K, and both the color rendering parameters CRI, R9, Rf and the color gamut index Rg and the like of the spectrum have higher values. Corresponding to the blue light-generating unit, the red light-generating unit and the green light-generating unit, spectral distribution of the light source 104 has relatively obvious, two spectral emission peaks.

For the first emission peak, its wavelength resides between 430 nm and 470 nm, it is generated by the blue light-generating unit, and a half-width of its emission spectrum is in the range of 15 nm to 35 nm. A luminous zone formed by green light generated by the green light-generating unit is distributed over a range of 510 nm to 580 nm, and the spectral distribution of green light is gentle. Taking 5 nm as a measuring interval, a relative difference between neighboring spectral intensities within a wavelength width of 5 nm is less than 15%.

For the second emission peak, its wavelength resides between 620 nm and 660 nm, it is produced by red fluorescent powders excited by blue light, and a spectral intensity of the second peak is the maximum value in the whole spectrum. The peak intensity of blue light, that is, the first peak, is 40% to 60% of the peak intensity of red light, that is, the second peak. A half-width of an emission spectrum of red fluorescent powders is in the range of 70 nm to 105 nm, and in a specific embodiment, the half-width of most of the red fluorophores in the present disclosure falls within following two ranges: 70 nm to 85 nm, and 95 nm to 105 nm.

As a feature of the present disclosure, under the same wavelength, a change rate of spectral intensity for neighboring wavelengths of a luminescent spectrum of the light source 104 is indicated by A1(λ), and a change rate of spectral intensity for neighboring wavelengths of a heat radiation spectrum of Planck blackbody radiation having the same color temperature with the light source 104 is indicted by A2(λ). A difference A(λ) between A1(λ) and A2(λ) falls within the region of [−3.0, 3.0], that is, −3.0≤A1(λ)−A2(λ)≤3.0, and in an embodiment, −1.5≤A1(λ)−A2(λ)≤1.5.

The term “neighboring” as used herein takes 5 nm as a computation interval, that is, when the change rate of spectral intensity for neighboring wavelengths is calculated, an interval of 5 nm is taken into account, and particular operational formulas for A1(λ) and A2(λ) are as follows:

$$A 1 ( λ ) = [ P ( λ ) * \frac{100}{\sum ( P ( λ ) * V ( λ ) )} - P ( λ - 1 ) * \frac{100}{\sum ( P ( λ ) * V ( λ ) )} ] ;$$

$$A 2 ( λ ) = [ R ( λ ) * \frac{100}{\sum ( R ( λ ) * V ( λ ) )} - R ( λ - 1 ) * \frac{100}{\sum ( R ( λ ) * V ( λ ) )} ] ,$$

where P(λ) is the luminescent spectrum of the light source, R(λ) is the luminescent spectrum of the heat radiator having the same color temperature with the light source in the visible light range, and V(λ) is a luminous efficiency function of a photopic vision spectrum.

The heat radiation spectrum is calculated according to the Planck blackbody radiation formula, and the computational formulas are as follows:

R(λ)=A/(exp(B)−1);

A=(2*h*c*c)/λ^{\hat{ }5};

B=(h*c)/(λ*k*CCT);

CCT is the color temperature value of the spectrum, h is the Planck constant which is 6.626E-34 joule*second, c is the speed of light, which is 3.000E8 m/s, and k is the Boltzmann constant coefficient, which is 1.38065E-23 kg*s⁻²*K⁻¹.

A color coordinate scope of the light color of the light source 104 is that, x is in the range between 0.410 and 0.450, and y is in the range between 0.375 and 0.415 (x=0.410˜0.450, y=0.375˜0.415); an example color coordinate scope is that x is in the range between 0.420 and 0.440, and y is in the range between 0.385 and 0.405 (x=0.420˜0.440, y=0.385˜0.405); and the scope is that, x is in the range between 0.425 and 0.435, and y is in the range between 0.390 and 0.400 (x=0.425˜0.435, y=0.390˜0.400). The color rendering parameters CRI, Rf of this spectrum each are no less than 90.0; R9 is no less than 70.0; and the gamut index Rg is no less than 100.0.

Several embodiments of the light source 104 will be introduced below.

In a first embodiment, the light source 104 is provided with: a blue LED chip with a peak wavelength of 450±5 nm which is used as a blue light-generating unit, a red fluorophore capable of converting part of blue light emitted by the blue light-generating unit into red light which is used as a red light-generating unit, and a green fluorophore capable of converting part of blue light emitted by the blue light-generating unit into green light which is used as a green light-generating unit. In the present embodiment, the blue light LED chip is used not only as the blue light-generating unit, but also as an excitation light source for the red light-generating unit and the green light-generating unit.

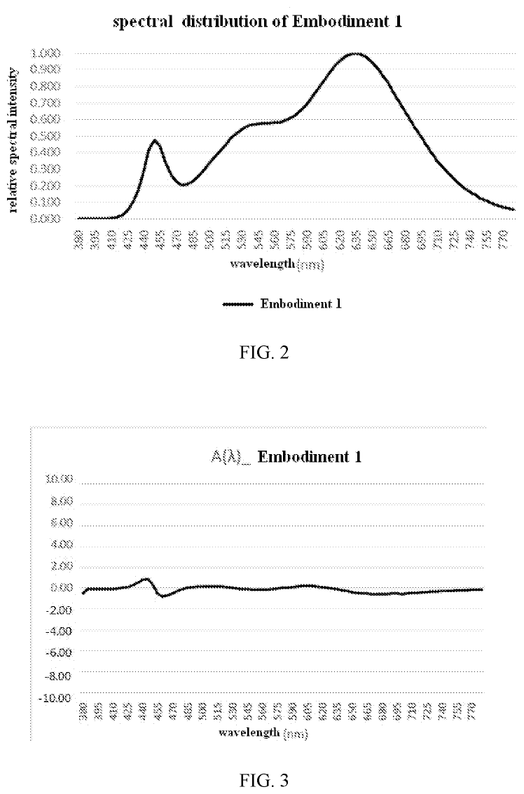

FIG. 2 is a relative spectral energy distribution diagram of the first embodiment of the present disclosure. A luminescent peak for forming a first peak in the figure by energy of blue light emitted by the blue light LED chip is at a wavelength of 450 nm, and a half-width FWHM is 21.8±5 nm (21.8 is a measured value of one light source, and because a slight divergence may be existed in actually measured values of the half-width for every light source of the same batch in actual production, there will be a positive/negative range, and the values below follow the same pattern). The green fluorophore converts part of the blue light emitted by the blue LED chip into green light. Within the range of 510 nm to 580 nm, by taking 5 nm as a measuring interval, the maximum value of a relative percentile difference between two neighboring spectral intensities with the same wavelength broadband is 0.11. The red fluorophore (a nitride fluorescent powder for this embodiment) converts part of blue light emitted by the blue LED chip into red light, which forms a second peak in FIG. 2. For the second peak, a luminescent peak is at a wavelength of 635 nm, and a half-width FWHM is 83.2±5 nm. A peak intensity of the first peak is about 47.6% of that of the second peak.

FIG. 3 shows the distribution of A (λ) in the first embodiment of the present disclosure, wherein A(λ)=A1(λ)−A2(λ), and as can be seen from the figure, a value of A(λ) is in the range between −0.78 and 0.85. A color coordinate of the first embodiment is x=0.4337 and y=0.3919 (x=0.4337, y=0. 0.3919), a color temperature is 2964K, color rendering indexes CRI=95.6, R9=95.8, Rf=93.4, and a gamut index Rg=105.6.

In a second embodiment, the light source 104 is provided with: a blue LED chip with a peak wavelength of 455±5 nm which is used as a blue light-generating unit, a red fluorophore capable of converting part of blue light emitted by the blue light-generating unit into red light which is used as a red light-generating unit, and a green fluorophore capable of converting part of blue light emitted by the blue light-generating unit into green light which is used as a green light-generating unit. In the present embodiment, the blue light LED chip is used not only as the blue light-generating unit but also as an excitation light source for the red light-generating unit and the green light-generating unit.

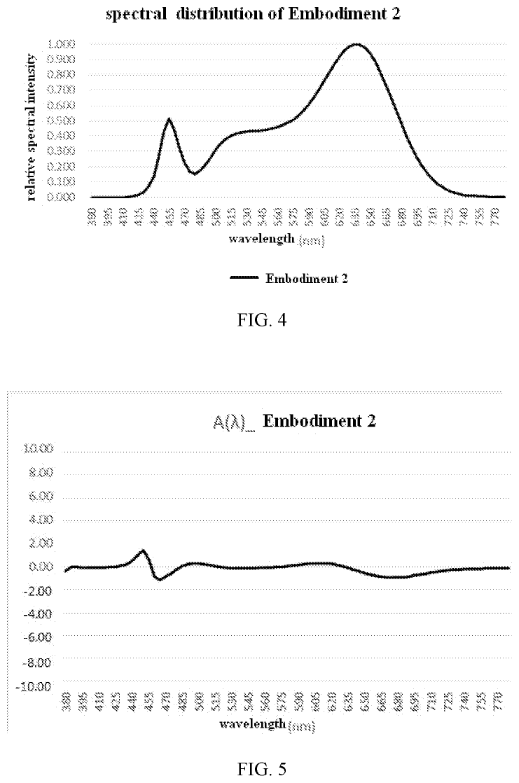

FIG. 4 is a relative spectral energy distribution diagram of the second embodiment of the present disclosure. A luminescent peak for forming a first peak in the figure by energy of blue light emitted by the blue light LED chip is at a wavelength of 455 nm, and a half-width FWHM is 22.3±5 nm. The green fluorophore (Ga-YAG in aluminate system for this embodiment) converts part of blue light emitted by the blue LED chip into green light. Within the range of 510 nm to 580 nm, by taking 5 nm as a measuring interval, the maximum value of a relative percentile difference between two neighboring spectral intensities with the same wavelength broadband is 0.09. The red fluorophore (a nitride fluorescent powder for this embodiment) converts part of blue light emitted by the blue LED chip into red light, which forms a second peak in FIG. 4. For the second peak, a luminescent peak is at a wavelength of 635 nm, and a half-width FWHM is 80.0±5 nm. A peak intensity of the first peak is about 51.6% of that of the second peak.

FIG. 5 shows the distribution of A (λ) in the second embodiment of the present disclosure, wherein A(λ)=A1(2)−A2(λ), and as can be seen from the figure, a value of A(λ) is in the range between −1.16 and 1.40. A color coordinate of the second embodiment is x=0.4438 and y=0.3835 (x=0.4438, y=0.3835), a color temperature is 2728K, color rendering indexes CRI=90.3, R9=80.9, Rf=91.6, and a gamut index Rg=107.2.

In a third embodiment, the light source 104 is provided with: a blue LED chip with a peak wavelength of 450±5 nm which is used as a blue light-generating unit, a red fluorophore capable of converting part of blue light emitted by the blue light-generating unit into red light which is used as a red light-generating unit, and a green fluorophore capable of converting part of blue light emitted by the blue light-generating unit into green light which is used as a green light-generating unit. In the present embodiment, the blue light LED chip is used not only as the blue light-generating unit but also as an excitation light source for the red light-generating unit and the green light-generating unit.

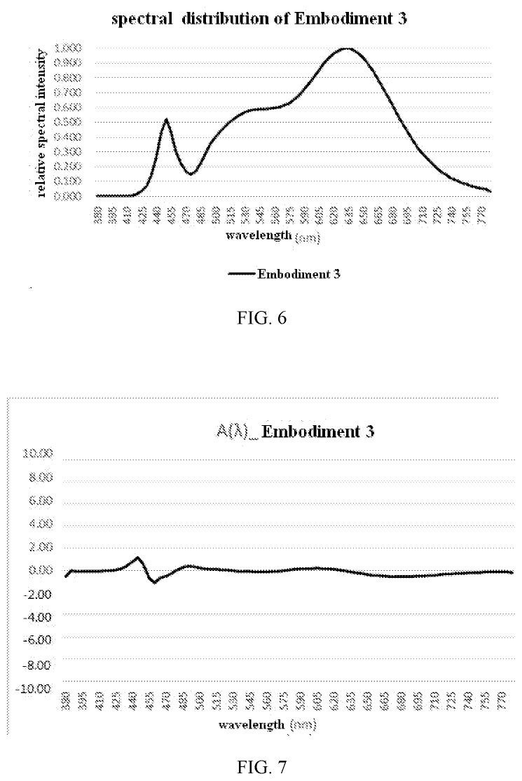

FIG. 6 is a relative spectral energy distribution diagram of the third embodiment of the present disclosure. A luminescent peak for forming a first peak in the figure by the energy of blue light emitted by the blue light LED chip is at a wavelength of 450 nm, and a half-width FWHM is 21.8±5 nm. The green fluorophore (Lu-AG in aluminate system for this embodiment) converts part of blue light emitted by the blue LED chip into green light. Within the range of 510 nm to 580 nm, by taking 5 nm as a measuring interval, the maximum value of a relative percentile difference between two neighboring spectral intensities with the same wavelength broadband is 0.08. The red fluorophore (a nitride fluorescent powder for this embodiment) converts part of blue light emitted by the blue LED chip into red light, which forms a second peak in FIG. 6. For the second peak, a luminescent peak is at a wavelength of 635 nm, and a half-width FWHM is 80.6±5 nm. A peak intensity of the first peak is about 52.1% of that of the second peak.

FIG. 7 shows the distribution of A (λ) in the third embodiment of the present disclosure, wherein A(λ)=A1(2)−A2(λ), and as can be seen from the figure, a value of A(λ) is in the range between −1.11 and 1.15. A color coordinate of the third embodiment is x=0.4348 and y=0.4014 (x=0.4348, y=0.4014), a color temperature is 3014K, color rendering indexes CRI=96.6, R9=97.5, Rf=95.5, and a gamut index Rg=103.0.

In a fourth embodiment, the light source 104 is provided with: a blue LED chip with a peak wavelength of 450±5 nm which is used as a blue light-generating unit, a red fluorophore capable of converting part of blue light emitted by the blue light-generating unit into red light which is used as a red light-generating unit, and a green fluorophore capable of converting part of blue light emitted by the blue light-generating unit into green light which is used as a green light-generating unit. In the present embodiment, the blue light LED chip is used not only as the blue light-generating unit, but also as an excitation light source for the red light-generating unit and the green light-generating unit.

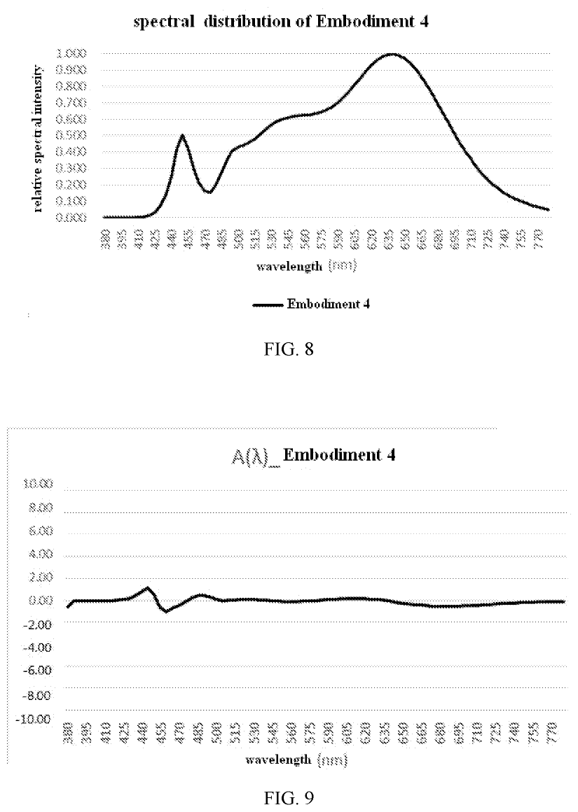

FIG. 8 is a relative spectral energy distribution diagram of the fourth embodiment of the present disclosure. A luminescent peak for forming a first peak in the figure by the energy of blue light emitted by the blue light LED chip is at a wavelength of 450 nm, and a half-width FWHM is 21.8±5 nm. The green fluorophore (Ga-YAG in aluminate system for this embodiment) converts part of blue light emitted by the blue LED chip into green light. Within the range of 510 nm to 580 nm, by taking 5 nm as a measuring interval, the maximum value of a relative percentile difference between two neighboring spectral intensities with the same wavelength broadband is 0.06. The red fluorophore (a nitride fluorescent powder for this embodiment) converts part of blue light emitted by the blue LED chip into red light, which forms a second peak in FIG. 8. For the second peak, a luminescent peak is at a wavelength of 640 nm, and a half-width FWHM is 96.4±5 nm. A peak intensity of the first peak is about 50.3% of that of the second peak.

FIG. 9 shows the distribution of A (λ) in the fourth embodiment of the present disclosure, wherein A(λ)=A1(2)−A2(λ), and as can be seen from the figure, a value of A(λ) is in the range between −1.06 and 1.10. A color coordinate of the fourth embodiment is x=0.4325 and y=0.4045 (x=0.4325, y=0.4045), a color temperature is 3080K, color rendering indexes CRI=97.3, R9=97.0, Rf=95.5, and a gamut index Rg=103.0.

In a fifth embodiment, the light source 104 is provided with: a blue LED chip with a peak wavelength of 450±5 nm which is used as a blue light-generating unit, a red fluorophore capable of converting part of blue light emitted by the blue light-generating unit into red light which is used as a red light-generating unit, and a green fluorophore capable of converting part of blue light emitted by the blue light-generating unit into green light which is used as a green light-generating unit. In the present embodiment, the blue light LED chip is used not only as the blue light-generating unit, but also as an excitation light source for the red light-generating unit and the green light-generating unit.

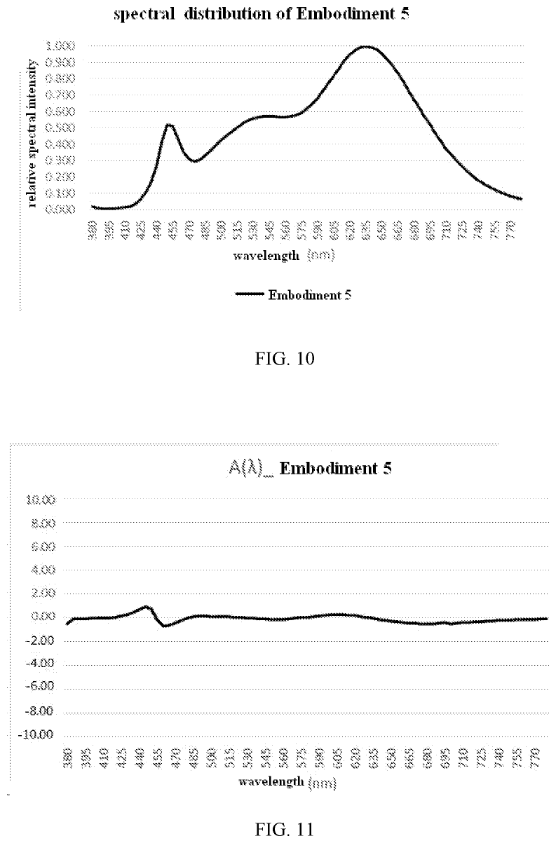

FIG. 10 is a relative spectral energy distribution diagram in the fifth embodiment of the present disclosure. A luminescent peak for forming a first peak in the figure by the energy of blue light emitted by the blue light LED chip is at a wavelength of 450 nm, and a half-width FWHM is 21.8±5 nm. The green fluorophore converts part of the blue light emitted by the blue LED chip into green light. Within the range of 510 nm to 580 nm, by taking 5 nm as a measuring interval, the maximum value of a relative percentile difference between two neighboring spectral intensities with the same wavelength broadband is 0.06. The red fluorophore (a nitride fluorescent powder in this embodiment) converts part of blue light emitted by the blue LED chip into red light, which forms a second peak in FIG. 10. For the second peak, a luminescent peak is at a wavelength of 635 nm, and a half-width FWHM is 80.0±5 nm. A peak intensity of the first peak is about 52.1% of that of the second peak.

FIG. 11 shows the distribution of A (λ) in the fifth embodiment of the present disclosure, wherein A(λ)=A1(λ)−A2(λ), and as can be seen from the figure, a value of A(λ) is in the range between −0.71 and 0.93. A color coordinate of the fifth embodiment is x=0.4194 and y=0.3840, a color temperature is 3163K, color rendering indexes CRI=92.4, R9=78.9, Rf=93.8, and a gamut index Rg=104.8.

The light color of the light source of the present disclosure is standard white, and its Duv is in the range between −5 and 5.

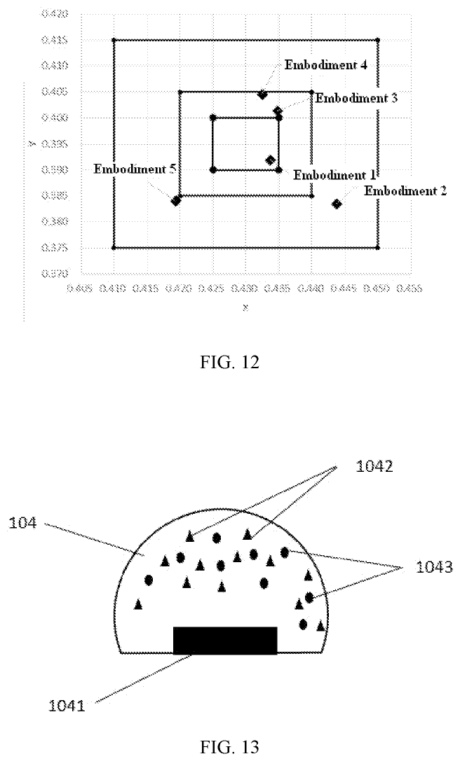

FIG. 12 shows the light color coordinates of the light sources 104 in Embodiments 1 to 5 in the CIE1931 color coordinate system, and it can be found that these points all fall within such a coordinate scope that x is in the range between 0.410 and 0.450 and y is in the range between 0.375 and 0.415 (x=0.410˜0.450, y=0.375˜0.415). Further, it's found that the first embodiment, the third embodiment, and the fourth embodiment achieve notable effects, and the color coordinate scope of these three embodiments is that, x is in the range between 0.420 and 0.440, and y is in the range between 0.385 and 0.405 (x=0.420˜0.440,y=0.385˜0.405). Moreover, in some embodiments, a preferred scope is that, x is in the range between 0.425 and 0.435, and y is in the range between 0.390 and 0.400 (x=0.425˜0.435, y=0.390˜0.400); the first embodiment is just within this scope.

In another example, light emitted by the light source further satisfies the condition that: given a same wavelength, e difference A(λ) between a change rate A1(0) of spectral intensities for neighboring wavelengths of a luminescent spectrum of the light source, and a change rate A2(λ) of spectral intensities for neighboring wavelengths of a heat dissipation spectrum of Planck blackbody radiation with a color temperature as same as that of the light source is within the range of [−3.0, 3.0].

In another example, the A(λ) is within the range of [−1.5, 1.5].

In another example, the half-width of the emission spectrum of the red light is within the range of 70 nm to 85 nm or the range of 95 nm to 105 nm.

In another example, the blue light-generating unit is a blue LED chip.

In another example, the green light-generating unit contains a green fluorophore which absorbs light emitted by the blue light-generating unit and emits green light through wavelength conversion.

In another example, the red light-generating unit contains a red fluorophore which absorbs light emitted by the blue light-generating unit and emits red light through wavelength conversion.

In another example, the blue light-generating unit, the green light-generating unit, and the red light-generating unit are integrally packaged, where the blue light-generating unit is a blue LED, the green light-generating unit is a green fluorophore which absorbs light emitted by the blue light-generating unit and emits green light through wavelength conversion, and the red light-generating unit is a red fluorophore which absorbs light emitted by the blue light-generating unit and emits red light through wavelength conversion.

In another example, the green fluorophore is of aluminate system or silicate system or nitride system or oxynitride system or a combination of any two thereof.

In another example, the red fluorophore is of nitride system or silicate system or a combination thereof.

In another example, the horizontal coordinate X is within the range of 0.420 to 0.440, and the longitudinal coordinate Y is within the range of 0.385 to 0.405.

In another example, the horizontal coordinate X is within the range of 0.425 to 0.435, and the longitudinal coordinate Y is within the range of 0.390 to 0.400.

In another example, a color temperature of the light emitted by the light source is within the range of 2500K to 3600K.

In another example, a color rendering parameter CRI of the light emitted by the light source is greater than 90.

In another example, a color rendering index Rf of the light emitted by the light source is greater than 90.

In another example, a color rendering index R9 of the light emitted by the light source is greater than 70.

In another example, a gamut index Rg of the light emitted by the light source is greater than 100.

The present disclosure further provides an illuminating device, including: the light source described above; and a power supply connected to the light source and configured to provide the light source with a working power.

In another example, the illuminating device further includes a controller, the controller is connected to the light source and configured to adjust the irradiation light emitted by the light source.

The light source provided by the present disclosure has a specific spectral distribution, in which not only an evaluation of illuminating effect under color theory but also an influence of a spectrum on an actual illuminating effect is considered, and meanwhile an impact of a luminous material on the spectrum is also taken into account. Thus, a light source that illuminates objects with high vividness, high color rendering index and high color gamut index can be obtained, and the light source can achieve an effect similar to a ceramic metal halide lamp.

The embodiments of the present disclosure have been described in detail with reference to the above particular embodiments. It should be understood that the above are only specific implementations of the present disclosure, and the protection scope of the present disclosure is not limited thereto. Any modifications, substitutions, and improvements that easily occur to those skilled in the art within the spirit and principle of the present disclosure should be fallen within the protection scope of the present disclosure.

What is claimed is:

1. A light source, comprising
a blue light-generating unit configured to emit blue light, wherein the blue light-generating unit is a blue LED chip;
a green light-generating unit configured to emit green light, wherein the green light-generating unit contains a green fluorophore that absorbs light emitted by the blue light-generating unit and emits green light through wavelength conversion; and
a red light-generating unit configured to emit red light, wherein the blue light-generating unit, the green light-generating unit, and the red light-generating unit are integrally packaged.

2. The light source according to claim 1,
wherein for the blue light, a peak wavelength is within the range of 430 nm to 470 nm, and a half-width of an emission spectrum is within the range of 15 nm to 35 nm;
wherein for the red light, a peak wavelength is within the range of 620 nm to 660 nm, and a half-width of an emission spectrum is within the range of 70 nm to 105 nm; wherein a peak intensity of the blue light is 40% to 60% of a peak intensity of the red light;
wherein for the green light, within a spectrum range of 510 nm to 580 nm, by taking 5 nm as a measuring interval, a relative difference of neighboring spectral intensities within a wavelength width of 5 nm is less than 15%; and
wherein irradiation light emitted by the light source satisfies such a condition in the CIE1931 color coordinate system that, a horizontal coordinate X is within the range of 0.410 to 0.450, and a longitudinal coordinate Y is within the range of 0.375 to 0.415.

3. The light source according to claim 2, wherein light emitted by the light source further satisfies the condition that: given a same wavelength, a difference A(λ) between a change rate A1(λ) of spectral intensities for neighboring wavelengths of a luminescent spectrum of the light source, and a change rate A2(λ) of spectral intensities for neighboring wavelengths of a heat dissipation spectrum of Planck blackbody radiation with a color temperature as same as that of the light source is within the range of [−3.0, 3.0].

4. The light source according to claim 3, wherein the A(λ) is within the range of [−1.5, 1.5].

5. The light source according to claim 3, wherein the half-width of the emission spectrum of the red light is within the range of 70 nm to 85 nm or the range of 95 nm to 105 nm.

6. The light source according to claim 1, wherein the red light-generating unit contains a red fluorophore that absorbs light emitted by the blue light-generating unit and emits red light through wavelength conversion.

7. The light source according to claim 6, wherein the green fluorophore is either an aluminate system, silicate system, nitride system, oxynitride system, or a combination of any two thereof.

8. The light source according to claim 7, wherein the red fluorophore is either a nitride system, silicate system, or a combination thereof.

9. The light source according to claim 1, wherein the horizontal coordinate X is within the range of 0.420 to 0.440, and the longitudinal coordinate Y is within the range of 0.385 to 0.405.

10. The light source according to claim 9, wherein the horizontal coordinate X is within the range of 0.425 to 0.435, and the longitudinal coordinate Y is within the range of 0.390 to 0.400.

11. The light source according to claim 1, wherein a color temperature of the light emitted by the light source is within the range of 2500K to 3600K.

12. The light source according to claim 11, wherein a color rendering parameter CRI of the light emitted by the light source is greater than 90.

13. The light source according to claim 11, wherein a color rendering index Rf of the light emitted by the light source is greater than 90.

14. The light source according to claim 11, wherein a color rendering index R9 of the light emitted by the light source is greater than 70.

15. An illuminating device, comprising
a blue light-generating unit configured to emit blue light, wherein the blue light-generating unit is a blue LED chip;
a green light-generating unit configured to emit green light, wherein the green light-generating unit contains a green fluorophore that absorbs light emitted by the blue light-generating unit and emits green light through wavelength conversion;
a red light-generating unit configured to emit red light; and
a power supply connected to the light source and configured to provide the light source with a working power.

16. The illuminating device according to claim 15, further comprising a controller, the controller is connected to the light source and configured to adjust the irradiation light emitted by the light source.

17. The illuminating device according to claim 15, wherein the blue light-generating unit, the green light-generating unit, and the red light-generating unit are integrally packaged; and
wherein the red light-generating unit is a red fluorophore that absorbs light emitted by the blue light-generating unit and emits red light through wavelength conversion.

18. The illuminating device according to claim 15, wherein the red light-generating unit contains a red fluorophore that absorbs light emitted by the blue light-generating unit and emits red light through wavelength conversion.

19. The illuminating device according to claim 15, wherein the green fluorophore is either an aluminate system, silicate system, nitride system, oxynitride system, or a combination of any two thereof.

20. The illuminating device according to claim 15, wherein the red fluorophore is either a nitride system, silicate system, or a combination thereof.
